(19) United States
(12) Patent Application Publication
(10) Pub. No.: US 2026/0318979 A1
(43) Pub. Date: Oct. 15, 2026

(54) TEST CIRCUIT AND TESTING METHOD

(71) Applicant: FUJI ELECTRIC CO., LTD., Kawasaki-shi (JP)

(72) Inventor: Ryouichi KAWANO, Matsumoto-city (JP)

(73) Assignee: FUJI ELECTRIC CO., LTD., Kawasaki-shi (JP)

(21) Appl. No.: 19/463,744

(22) Filed: Jan. 29, 2026

(30) Foreign Application Priority Data
Feb. 21, 2025 (JP) 2025-026348

(51) Int. Cl. G01R 31/26; G01R 1/20; G01R 1/28

(52) U.S. Cl. CPC G01R 31/2621; G01R 1/203; G01R 1/28; G01R 31/2642

(57) ABSTRACT

A test circuit for conducting a test on a switching device having a power-supply-side electrode, a ground-side electrode and a control electrode. The test circuit includes: a first terminal for receiving a drive signal to turn on and off the switching device; a second terminal for connecting to the ground-side electrode of the switching device; a third terminal for connecting to the control electrode of the switching device; a fourth terminal for connecting to the power-supply-side electrode of the switching device; a fifth terminal for receiving a power supply voltage; a coil connected between the fourth and fifth terminals; and a clamp circuit connected between the second and fourth terminals. The clamp circuit has a clamp voltage that is higher than a withstand voltage between the power-supply-side electrode and the ground-side electrode, and lower than a breakdown voltage between the power-supply-side electrode and the ground-side electrode.

### CROSS-REFERENCE TO RELATED APPLICATIONS

The present application claims priority pursuant to 35 U.S.C. § 119 from Japanese patent application number 2025-026348 filed on Feb. 21, 2025, the entire disclosure of which is hereby incorporated by reference herein.

### BACKGROUND

### Technical Field

The present disclosure relates to a test circuit and a testing method.

### Description of the Related Art

Switching device products such as power Metal Oxide Semiconductor Field Effect Transistors (MOSFETs) and Insulated Gate Bipolar Transistor (IGBTs) include two types: avalanche-proof products and non-avalanche-proof products. It is known that when screening tests are conducted on non-avalanche-proof products to select products with defects such as initial failures and the like, a switch for current interruption (for example, Japanese Patent Application Publication No. 2013-92534) or a clamp circuit (for example, Japanese Patent Application Publication Nos. 2013-251671, 2016-167693, 2012-32327, and 2023-62811) is used to protect a device.

However, even if a configuration is made such that a current is to be as in Japanese Patent Application Publication No. 2013-92534, it may take time until the current has been interrupted, and thus there is an issue that damage to a switching device cannot be completely prevented. Further, the clamp circuits of Japanese Patent Application Publication Nos. 2013-251671, 2016-167693, 2012-32327, and 2023-62811 may be unable to accurately evaluate non-avalanche-proof products.

### SUMMARY

A main aspect of the present disclosure is a test circuit to be used in conducting a test on a switching device having a power-supply-side electrode, a ground-side electrode and a control electrode, the test circuit comprising: a first terminal configured to receive a drive signal to turn on and off the switching device; a second terminal configured to be connected to the ground-side electrode of the switching device; a third terminal configured to be connected to the control electrode of the switching device; a fourth terminal configured to be connected to the power-supply-side electrode of the switching device; a fifth terminal configured to receive a power supply voltage; a coil connected between the fourth terminal and the fifth terminal; and a clamp circuit connected between the second terminal and the fourth terminal, wherein the clamp circuit has a clamp voltage that is higher than a withstand voltage between the power-supply-side electrode and the ground-side electrode of the switching device, and lower than a breakdown voltage between the power-supply-side electrode and the ground-side electrode of the switching device.

### BRIEF DESCRIPTION OF THE DRAWINGS

FIG. 1 is a circuit diagram illustrating an example of a test circuit 1.

FIG. 2 is a circuit diagram illustrating an example of a test circuit 10.

FIG. 3 is a table illustrating the relationship between the conditions under which an avalanche test was conducted on a switching device S1 and the breakdown voltage obtained as a result of the avalanche test on the switching device S1.

FIG. 4 is a waveform diagram illustrating the waveforms of a voltage Vge, a voltage Vce, and a collector current Ic when a switching device S1 has been instantaneously damaged as a result of an avalanche test conducted on a switching device S1 using a test circuit 10.

FIG. 5 is a waveform diagram illustrating the waveforms of a voltage Vge, a voltage Vce, and a collector current Ic when an avalanche test was conducted on a switching device 3 using a test circuit 1.

### DETAILED DESCRIPTION

At least following matters will become apparent from the descriptions of the present description and the accompanying drawings. Hereinafter, the present disclosure will be described in accordance with an embodiment with reference to the accompanying drawings.

A large number of power semiconductor devices (hereinafter referred to as switching devices) such as power Metal Oxide Semiconductor Field Effect Transistors (MOSFETs) and Insulated Gate Bipolar Transistor (IGBTs) are formed in a wafer substrate. Then, these switching devices will be divided by dicing and then being incorporated into a semiconductor module. It is assumed that such a switching device to be subjected to a screening test in an embodiment of the present disclosure is an IGBT, for example.

A screening test is a test to evaluate whether the switching device operates normally and screens out (selects) the switching device having a defect such as an initial failure and the like, and is usually performed on the switching device in the state of a chip before being incorporated into the semiconductor module. Such screening tests include dynamic performance tests such as a switching test, an L-load avalanche test (hereinafter also referred to simply as avalanche test), and the like and static performance tests such as an interelectrode leakage current test, a static withstand voltage test and the like. It is assumed in an embodiment of the present disclosure that the avalanche test, which is one of dynamic performance tests, is to be conducted on the switching device to be tested.

Test circuit 1

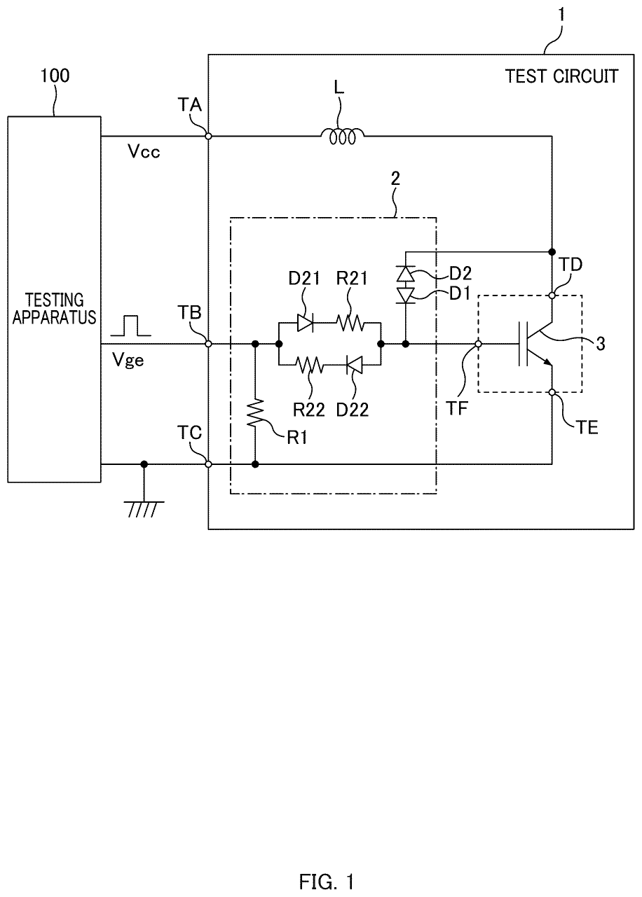

FIG. 1 is a circuit diagram illustrating an example of a test circuit 1 of an embodiment of the present disclosure. The test circuit 1 includes terminals TA to TF, a coil L, and a clamp circuit 2. The above-mentioned elements included in the test circuit 1 may be provided to a single substrate, or may be provided separately to multiple substrates.

The testing apparatus 100 is an apparatus that performs the avalanche test on the switching device 3 through the test circuit 1. The testing apparatus 100 includes: a power supply (not illustrated) that supplies a power supply voltage Vcc, a driver circuit (not illustrated) that outputs a drive signal (pulse signal) to turn on and off the switching device 3; and a microcomputer (not illustrated) that controls the operation of each portion of the test circuit 1; and the like. Furthermore, the testing apparatus 100 also includes a detection circuit (not illustrated) that detects an abnormality such as an overcurrent by monitoring current values and voltage values in the avalanche test.

The terminal TA (fifth terminal) is a terminal to receive the power supply voltage Vcc from the testing apparatus 100. The terminal TB (first terminal) is a terminal to receive the drive signal for the switching device 3 from the testing apparatus 100.

The terminal TC is a terminal to receive a voltage at a ground level from the testing apparatus 100.

The terminal TD (fourth terminal) is a terminal connected to the collector electrode (hereinafter, simply referred to also as collector) of the switching device 3, which is a power-supply-side electrode. The terminal TD is connected to the terminal TA through the coil L within the test circuit 1.

The terminal TE (second terminal) is a terminal connected to the emitter electrode (hereinafter, simply referred to also as emitter) of the switching device 3, which is a ground-side electrode. The terminal TE is connected to the terminal TC within the test circuit 1.

The terminal TF (third terminal) is a terminal connected to the gate electrode (hereinafter, simply referred to also as gate) of the switching device 3, which is the control electrode thereof. The terminal TF is connected to the terminal TB within the test circuit 1.

Note that the switching device 3 to be used in the avalanche test is in the chip state before being incorporated into the semiconductor module.

The coil L is an inductive load connected between the terminal TA and the terminal TD, to thereby receive the power supply voltage Vcc from the testing apparatus 100 through the terminal TA.

The clamp circuit 2 has a clamp voltage Vclp to clamp the voltage Vce between the collector and the emitter of the switching device 3, so as to be able to properly evaluate the switching device 3 while operating it in avalanche mode, when the switching device 3 is turned off from an on state in response to the drive signal inputted from the testing apparatus 100 through the terminal TB. The value of this clamp voltage Vclp will be described later.

The clamp circuit 2 includes a first diode D1, a second diode D2, a third diode D21, a fourth diode D22, a first resistor R1, a second resistor R21, and a third resistor R22.

The second diode D2 is a diode to generate the clamp voltage of the clamp circuit 2. Note that there is one single second diode D2 in FIG. 1, however, depending on the value of the clamp voltage to be generated, multiple second diodes D2 may be prepared, and the multiple second diodes D2 may be connected in series. The first diode D1 is a diode for reverse current protection. The cathode of the first diode D1 is connected to the terminal TF. The anode of the second diode D2 is connected to the anode of the first diode D1. The anode of the first diode D1 is connected to the anode of the second diode D2. In other words, the first diode D1 and the second diode D2, which are oriented in directions opposite to each other, are connected in series between the terminal TD and the terminal TF. The first diode D1 and the second diode D2 constitute a Zener diode.

The first resistor R1, the second resistor R21, and the third resistor R22 are resistors to generate a voltage at the terminal TF. The switching device 3 is turned on and off according to the value of the voltage generated at the terminal TF.

The first resistor R1 is connected between the terminal TE and the terminal TF. The first resistor R1 has one end connected to the terminals TC and TE, and the other end connected to the terminal TB and connected also to the terminal TF through the clamp circuit 2.

The third diode D21 has an anode connected to the terminal TB, and a cathode connected to the terminal TF through the second resistor R21. In other words, the third diode D21 and the second resistor R21 are connected in series between the terminal TB and the terminal TF. Note that the third diode D21 and the second resistor R21 may be connected in series such that the cathode of the third diode D21 is connected to the terminal TF and the anode of the third diode D21 is connected to the terminal TB through the second resistor R21.

The anode of the fourth diode D22 is connected to the terminal TF, and the cathode of the fourth diode D22 is connected to the terminal TB through the third resistor R22. In other words, the fourth diode D22 and the third resistor R22 are connected in series between the terminal TB and the terminal TF. Note that the fourth diode D22 and the third resistor R22 may be connected in series such that the cathode of the fourth diode D22 is connected to terminal TB and the anode of the fourth diode D22 is connected to terminal TF through the third resistor R22.

The series body constituted by the third diode D21 and the second resistor R21 is connected in parallel with the series body constituted by the fourth diode D22 and the third resistor R22. The resistance value of the third resistor R22 is greater than the resistance value of the second resistor R21. Note that the resistance value of the third resistor R22 is set such that the clamp voltage of the clamp circuit 2 will be at the voltage level at which the switching device 3, which is a non-avalanche proof product, is not instantaneously damaged when the drive signal inputted to terminal TB falls, in other words, the resistance value is set in time for the clamp voltage of the clamp circuit 2 to reach the above voltage value. Meanwhile, the resistance value of the second resistor R21 only has to be set to a value smaller than the resistance value of the third resistor R22 so that an efficient test can be conducted with the test time for the avalanche test being reduced when the drive signal (Vge) inputted to the terminal TB rises.

In response to the drive signal inputted to the terminal TB rising to turn on the switching device 3, the third diode D21 is electrically connected, to thereby connect the terminal TB and the terminal TF through the second resistor R21. On the other hand, in response to the drive signal inputted to the terminal TB falling to turn off the switching device 3, the fourth diode D22 is electrically connected, to thereby connect the terminal TB and the terminal TF through the third resistor R22 having a resistance value greater than the resistance value of the second resistor R21. As such, the path between the terminal TB and the terminal TF is different depending on when the switching device 3 is turned on or when it is turned off.

Note that instead of providing the third diode D21, the fourth diode D22, the second resistor R21, and the third resistor R22 in the clamp circuit 2, a variable resistor (not illustrated) may be provided, which is designed so as to have a resistance value of the second resistor R21 upon rising of the drive signal inputted to the terminal TB, and to have a resistance value of the third resistor R22 upon falling of the drive signal inputted to the terminal TB.

### Clamp Voltage of Clamp Circuit 2

In the avalanche test, in response to the drive signal inputted to the terminal TB falling from a rising state, the switching device 3, which is the non-avalanche-proof product connected to the test circuit 1, is turned off from its on state. In this event, the clamp voltage Vclp of the clamp circuit 2 is determined so as to prevent the switching device 3 from being instantaneously damaged due to the energy stored in the coil L, and further so as to be able to properly evaluate the switching device 3 while operating in avalanche mode. Specifically, the clamp voltage Vclp of the clamp circuit 2 is determined to be any voltage within a range that is higher than the collector-emitter withstand voltage of the switching device 3 and lower than the collector-emitter breakdown voltage of the switching device 3. Note that the withstand voltage refers to the maximum value (limit value) of the voltage that can be applied between the collector and the emitter of the switching device 3. Further, the breakdown voltage refers to the voltage that is higher than the withstand voltage and is generated between the collector and the emitter when the switching device 3 has been actually instantaneously damaged as a result of conducting the avalanche test on the switching device 3.

In an embodiment of the present disclosure, multiple switching devices S1, which are non-avalanche-proof products and have the same specifications as those of the switching device 3, are prepared as samples, the avalanche test has been conducted on the multiple switching devices S1, and as a result, the clamp voltage Vclp of the clamp circuit 2 is determined from the voltages in the range that is higher than the maximum value of the withstand voltages specified for the multiple switching devices S1 and lower than the minimum value of the breakdown voltages of the multiple switching devices S1.

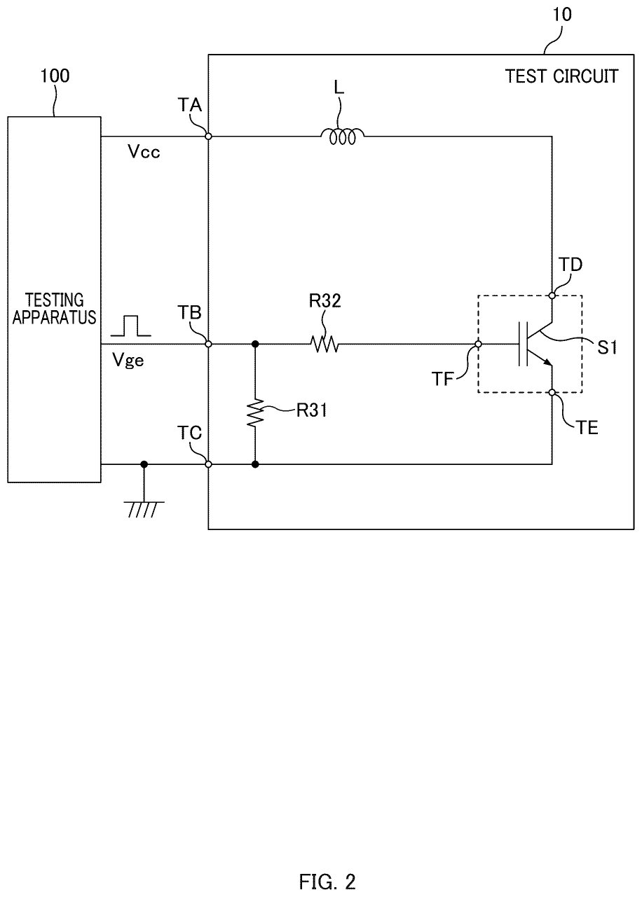

FIG. 2 is a circuit diagram illustrating an example of a test circuit 10 to be used in conducting the avalanche tests on the multiple switching devices S1 that are samples. Note that, in the test circuit 10, the parts thereof that are the same as those in the test circuit 1 are given the same reference numerals and descriptions thereof are omitted.

The test circuit 10 is a circuit that is prepared to obtain the breakdown voltage generated between the collector and the emitter when the switching device S1 is actually instantaneously damaged as a result of the avalanche test conducted on the multiple switching devices S1, and thus does not need to include the clamp circuit 2 of the test circuit 1. The test circuit 10 includes resistors R31 and R32 instead of the clamp circuit 2. The resistor R31 is connected between the terminal TB and the terminal TC (also between the terminal TB and the terminal TE). The resistor R32 is connected between the terminal TB and the terminal TF. When the avalanche test is conducted, the gates of the multiple switching devices S1 to be tested are connected to the terminal TF, the collectors thereof are connected to the terminal TD, and the emitters thereof are connected to the terminal TE, and thus, the resistor R32 results in the gate resistor of the multiple switching devices S1. It is assumed in an embodiment of the present disclosure that, for example, a total of nine switching devices S11 to S19 are prepared as the multiple switching devices S1, and the switching devices S11 to S19 are connected to the test circuit 10, to conduct the avalanche test.

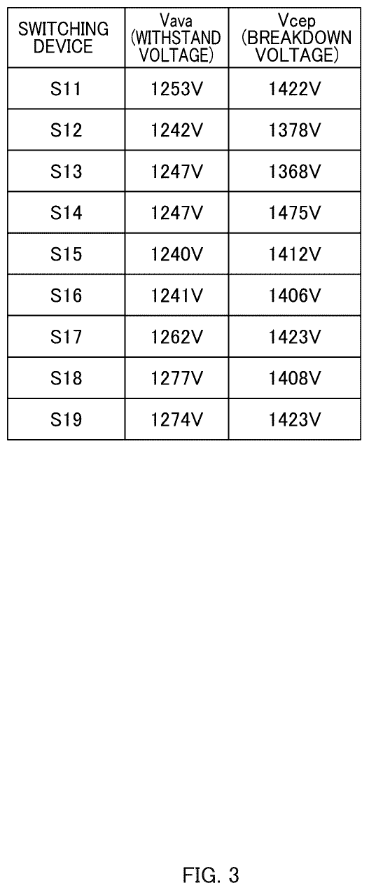

FIG. 3 is a table illustrating the relationship with the breakdown voltages Vcep obtained as a result of conducting the avalanche test conducted on the nine switching devices S11 to S19. Note that Vava (V) indicates the collector-emitter withstand voltages respectively specified for the switching devices S11 to S19. The withstand voltages Vava of the switching devices S11 to S19 are, for example, 1253 V, 1242 V, 1247 V, 1247 V, 1240 V, 1241 V, 1262 V, 1277 V, and 1274 V, respectively.

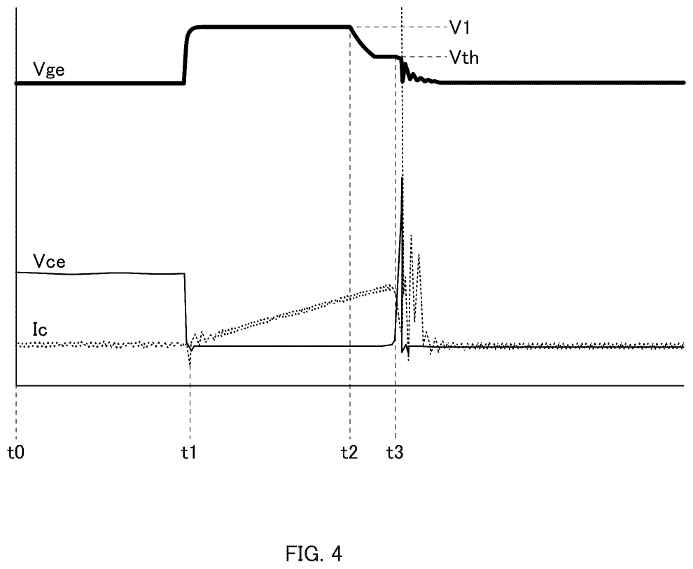

FIG. 4 is a waveform diagram illustrating the waveforms of the voltage Vge, the voltage Vce, and the collector current Ic when the switching device S1 has been instantaneously damaged as a result of conducting the avalanche test on the switching device S1 using the test circuit 10. In FIG. 4, the voltage Vge is given by a solid line, the voltage Vce is given by a thin solid line, and the collector current Ic is given by a dashed line. It is assumed that FIG. 4 illustrates the waveforms when the switching device S11 has been instantaneously damage, for example. However, when the avalanche test is conducted on other switching devices S12 to S19 as well, it is possible to obtain the waveforms similar to those obtained when the avalanche test is conducted on the switching device S11.

First, at time t0, the supply of the power supply voltage Vcc from the testing apparatus 100 to the terminal TA of the test circuit 10 is started.

Next, in response to the voltage Vge of the drive signal inputted to the terminal TB of the test circuit 10 from the testing apparatus 100 rising from 0 V to a voltage V1 that is higher than the threshold voltage Vth of the switching device S11 at time t1, the switching device S11 is turned on, the collector-emitter voltage Vce of the switching device S11 drops toward 0 V, and the collector current Ic flowing between the collector and the emitter of the switching device S11 begins to increase.

Next, the voltage Vge begins to drop at time t2, and in response to the voltage Vge falling below the threshold voltage Vth at time t3, the switching device S11 is turned off, the collector current Ic decreases, and the voltage Vce rises. In this event, the voltage Vce rises to a value greater than the withstand voltage Vava of the switching device S11 due to the energy stored in the coil L, which results in the switching device S11 being instantaneously damaged. The breakdown voltage when the switching device S11 has been instantaneously damaged can be obtained from a voltmeter (not illustrated) connected between the collector and the emitter of the switching device S11. The breakdown voltage when the switching device S11 actually has been instantaneously damaged is, for example, 1422 V.

The breakdown voltage when the switching devices S12 to S19 actually have been instantaneously damaged as a result of conducting the avalanche test on the switching devices S12 to S19 as in the case of the switching device S11 are, for example, 1378 V, 1368 V, 1475 V, 1412 V, 1406 V, 1423 V, 1408 V, and 1423 V, respectively.

The maximum value of the withstand voltages Vava is 1277 V, which is given as the withstand voltage of the switching device S18. Further, the minimum value of the breakdown voltage Vcep is 1368 V, which is given as the voltage when the switching device S13 actually has been instantaneously damaged. Thus, the clamp voltage Vclp of the clamp circuit 2 is determined to be one (for example, 1351 V) of the voltages within the range that is higher than 1277 V and lower than 1368 V, based on the results of the avalanche test using the switching devices S11 to S19. In practice, the clamp voltage Vclp is determined by the number of stages of the second diodes D2 that are connected in series, comprehensively considering the value of the power supply voltage Vcc applied to the terminal TA, the inductance value of the coil L, the value of the voltage Vge, the resistance value of the resistor R32, an ambient temperature Tj, the withstand voltage of the switching device 3, and the like. The clamp voltage Vclp is determined to be higher than the withstand voltage of the switching device 3 to be tested.

### Avalanche Test Using Test Circuit 1

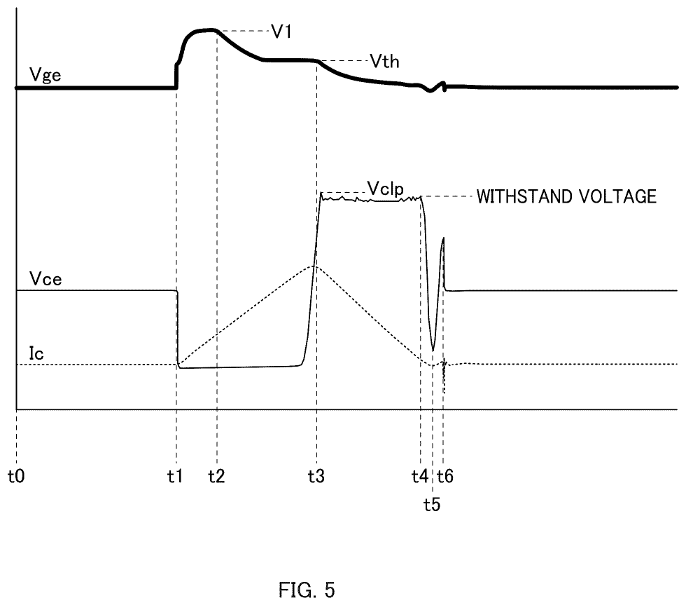

FIG. 5 is a waveform diagram illustrating the waveforms of the voltage Vge, the voltage Vce, and the collector current Ic when the avalanche test of the switching device 3 was conducted using the test circuit 1. In FIG. 5, the voltage Vge is given by a solid line, the voltage Vce is given by a thin solid line, and the collector current Ic is given by a dashed line. It is assumed that the clamp circuit 2 of the test circuit 1 has the clamp voltage Vclp determined as described above, and in conducting the avalanche test of the switching device 3 using the test circuit 1, the gate of the switching device 3 is connected to the terminal TF, the collector thereof is connected to the terminal TD, and the emitter thereof is connected to the terminal TE.

First, at time t0, the supply of the power supply voltage Vcc from the testing apparatus 100 to the terminal TA of the test circuit 1 is started.

In response to the voltage Vge of the drive signal inputted to the terminal TB of the test circuit 1 rising from 0 V to the voltage V1 that is higher than the threshold voltage Vth of the switching device 3 at time t1, the switching device 3 is turned on, the voltage Vce generated between the collector and the emitter of the switching device 3 drops toward 0 V, and the collector current Ic flowing between the collector and the emitter of the switching device 3 begins to increase.

The voltage Vge begins to drop towards 0V at time t2, and in response to the voltage Vge falling below the threshold voltage Vth at time t3, the switching device 3 is turned off, the voltage Vce begins to rise, and the collector current Ic begins to decrease from its peak value.

The increase in the voltage Vce is restrained by the clamp circuit 2, resulting in the voltage Vce being at the clamp voltage Vclp of the clamp circuit 2. Accordingly, the switching device 3 will no longer be instantaneously damaged due to the energy stored in the coil L.

In response to the voltage Vce being clamped by the clamp circuit 2 at time t3, the voltage Vce remains at the withstand voltage of the switching device 3 until time t4, thereby being able to operate the switching device 3 in avalanche mode.

At time t5, the collector current Ic decreases to 0 A. After resonating from time t4 to time t6, the voltage Vce returns to the voltage before time t1 prior to the rising of the voltage Vge.

As such, with the clamp circuit 2 having the clamp voltage Vclp determined as described above being provided to the test circuit 1, it becomes possible to properly evaluate the switching device 3, which is a non-avalanche-proof product, while operating it in avalanche mode, in the avalanche test on the switching device 3.

### SUMMARY

As described above, the test circuit 1 to be used in conducting the avalanche test on the switching device 3 includes: the terminal TB to receive the drive signal to turn on and off the switching device 3; the terminal TE connected to the emitter of the switching device 3; the terminal TF connected to the gate of the switching device 3; the terminal TD connected to the collector of the switching device 3; the terminal TA to receive the power supply voltage Vcc; the coil L connected between the terminal TD and the terminal TA; and the clamp circuit 2 connected between the terminal TD and the terminal TE, wherein the clamp circuit 2 has the clamp voltage Vclp that is higher than the withstand voltage between the gate and the emitter and lower than the breakdown voltage between the gate and the emitter.

According to the test circuit 1, it becomes possible to properly evaluate the switching device 3, which is a non-avalanche-proof product, while operating it in avalanche mode, in the avalanche test of the switching device 3.

Further, the clamp circuit 2 includes the first diode D1 having a cathode connected to the terminal TF and an anode, the second diode D2 having an anode connected to the anode of the first diode D1 and a cathode connected to the terminal TD, and the first resistor R1 connected between the terminal TE and the terminal TF.

According to the test circuit 1, it is possible to clamp the collector-emitter voltage Vce of the switching device 3 to a predetermined voltage.

Further, the test circuit 1 includes: the third diode D21 connected between the terminal TB and the terminal TF such that the anode thereof is closer to the terminal TB and the cathode thereof is closer to the terminal TF; the second resistor R21 that is located between the terminal TB and the terminal TF and connected in series with the third diode D21; the fourth diode D22 connected such that the cathode thereof is closer to the terminal TB and the anode thereof is closer to the terminal TF; and the third resistor R22 that is located between the terminal TB and the terminal TF, and is connected in series with the fourth diode D22, wherein the third diode D21 and the second resistor R21 are connected in parallel with the fourth diode D22 and the third resistor R22, and the resistance value of the third resistor R22 is greater than the resistance value of the second resistor R21.

According to the test circuit 1, when the switching device 3 has been turned off, the collector-emitter voltage Vce of the switching device 3 rising due to the energy stored in the coil L can be reliably restrained to the clamp voltage Vclp of the clamp circuit 2, thereby being able to prevent the switching device 3 from being instantaneously damaged.

The present disclosure is directed to provision of a test circuit and a testing method capable of properly evaluating a non-avalanche proof product, which is one type of switching devices, while operating it in avalanche mode.

According to the present disclosure, it becomes possible to properly evaluate a non-avalanche proof product, which is one type of switching devices, while operating it in avalanche mode.

An embodiment of the present disclosure described above is simply to facilitate understanding of the present disclosure and is not in any way to be construed as limiting the present disclosure. The present disclosure may variously be changed or altered without departing from its essential features and encompass equivalents thereof.

What is claimed is:

1. A test circuit to be used in conducting a test on a switching device having a power-supply-side electrode, a ground-side electrode and a control electrode, the test circuit comprising:
a first terminal configured to receive a drive signal to turn on and off the switching device;
a second terminal configured to be connected to the ground-side electrode of the switching device;
a third terminal configured to be connected to the control electrode of the switching device;
a fourth terminal configured to be connected to the power-supply-side electrode of the switching device;
a fifth terminal configured to receive a power supply voltage;
a coil connected between the fourth terminal and the fifth terminal; and
a clamp circuit connected between the second terminal and the fourth terminal, wherein
the clamp circuit has a clamp voltage that is higher than a withstand voltage between the power-supply-side electrode and the ground-side electrode of the switching device, and lower than a breakdown voltage between the power-supply-side electrode and the ground-side electrode of the switching device.

2. The test circuit according to claim 1, wherein the clamp circuit includes
a first diode, having
a cathode connected to the third terminal, and
an anode,
a second diode, having
an anode connected to the anode of the first diode, and
a cathode connected to the fourth terminal, and
a first resistor connected between the second terminal and the third terminal.

3. The test circuit according to claim 2, further comprising:
a third diode connected between the first terminal and the third terminal, such that an anode thereof is closer to the first terminal and a cathode thereof is closer to the third terminal;
a second resistor that is located between the first terminal and the third terminal, and is connected in series with the third diode;
a fourth diode connected between the first terminal and the third terminal, such that a cathode thereof is closer to the first terminal and an anode thereof is closer to the third terminal; and
a third resistor that is located between the first terminal and the third terminal, and is connected in series with the fourth diode, wherein
the third diode and the second resistor are connected in parallel with the fourth diode and the third resistor, and
a resistance value of the third resistor is greater than a resistance value of the second resistor.

4. A testing method of conducting a test on a switching device having a power-supply-side electrode, a ground-side electrode and a control electrode, the testing method comprising:
providing a test circuit that includes
a first terminal configured to receive a drive signal to turn on and off the switching device,
a second terminal configured to be connected to the ground-side electrode of the switching device,
a third terminal configured to be connected to the control electrode of the switching device,
a fourth terminal configured to be connected to the power-supply-side electrode of the switching device,
a fifth terminal configured to receive a power supply voltage,
a coil connected between the fourth terminal and the fifth terminal, and
a clamp circuit connected between the second terminal and the fourth terminal,
a first step of setting a value of a clamp voltage of the clamp circuit to a value that is higher than a withstand voltage between the power-supply-side electrode and the ground-side electrode of the switching device, and lower than a breakdown voltage between the power-supply-side electrode and the ground-side electrode of the switching device; and
a second step of conducting the test using the clamp circuit having the clamp voltage set in the first step.
